(19) United States
(12) Patent Application Publication
(10) Pub. No.: US 2004/0248353 A1
(43) Pub. Date: Dec. 9, 2004

(54) Processor and semiconductor integrated circuit

(75) Inventor: Satoshi Inoue, Chiba-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/687,629

(22) Filed: Oct. 20, 2003

(30) Foreign Application Priority Data
Jun. 4, 2003 (JP) 2003-159174

(51) Int. Cl. H01L 21/8238

(52) U.S. Cl. 438/200

(57) ABSTRACT

A processor includes a processor core having a general-purpose register, an instruction decoder, and an execution unit. An extension unit includes another execution unit connected to the processor core; and, a direct memory access controller is connected to both the processor core and the extension unit.

### CROSS REFERENCE TO RELATED APPLICATIONS

This application is based upon and claims the benefit of priority from prior Japanese Patent Applications P2003-159174 filed on Jun. 4, 2003; the entire contents of which are incorporated by reference herein.

### BACKGROUND OF THE INVENTION

1. Field of the Invention

The present invention relates to a processor. In particular, the invention relates to a processor and a semiconductor large scale integration (LSI) circuit, which includes an extensible processor or a reconfigurable calculation unit.

2. Description of the Related Art

A extensible processor core is a processor in which the performance can be enhanced by attaching an extension unit. The external unit may be implemented by a logic circuit such as a reconfigurable calculation circuit that is suitable for an application, external of the processor core (e.g., M. Borgatti et.al., “A Reconfigurable System featuring Dynamically Extensible Embedded Microprocessor, FPGA and Customisable I/O”, IEEE 2002 CUSTOM INTEGRATED CIRCUITS CONFERENCE, 2-3-l, p. 13-16).

Alternatively, there is a conventional custom processor that enhances the performance of the processor by connecting an extension circuit, which is designed by a user or provided by a vendor, externally of the processor core. The external circuit may be a calculation unit for a single cycle, a complex calculation unit for a plurality of cycles, or a coprocessor (for example, F. Lertora, “A Customized Processor for Face Recognition”, Embedded Processor Forum, May 1, 2002. (www.MDRonline.com)).

The extensible processor core can configure a highly efficient calculation unit by executing a plurality of applications on a large scale integration (LSI) circuit, and/or changing the function of the extension unit by its application using a logic circuit such as a reconfigurable field programmable gate array for the extension unit. The reconfigurable logic circuit, however, operates at a lower speed than that of general application specific integration circuits (ASIC).

Namely, the extension unit is slower than the processor core that utilizes ASIC cells. Therefore, synchronization between the processor core and the extension unit is necessary.

Furthermore, there is a problem with the above-mentioned processor in that even though high performance is provided by designing the extension unit applicable to an application and connecting it to the processor core, designing of the extension unit for each application is required, which increases development time and costs.

### SUMMARY OF THE INVENTION

An aspect of the present invention inheres in an extensive processor including a processor core having a general purpose register, an instruction decoder, and a second execution unit; an extension unit having a first execution unit that is connected to the processor core; and a direct memory access controller connected to both the processor core and the extension unit.

Another aspect of the present invention inheres in a semiconductor LSI circuit including a semiconductor chip; a processor core that is integrated on the semiconductor chip and includes a general purpose register, an instruction decoder, and a second execution unit; an extension unit that is integrated on the semiconductor chip and includes a first execution unit connected to the processor core; and a direct memory access controller that is integrated on the semiconductor chip and connected to both the processor core and the extension unit.

### BRIEF DESCRIPTION OF DRAWINGS

FIG. 1 shows an illustrative block diagram of an extensive processor as a comparative example according to the present invention;

FIG. 2 shows a basic structure of an extensive processor according to the first embodiment of the present invention;

FIG. 3 shows an illustrative block diagram of an extensive processor according to the first embodiment of the present invention;

FIG. 4 shows an illustrative structure example of a clock disable signal generation circuit, which is used with an extensive processor according to the first embodiment of the present invention;

FIG. 5 shows instruction structure examples for the processor core and the extension unit relative to a clock CLK in the case where the instructions for the extension unit are also executed with the same clock count as that for the processor core, according to the extensible processor of the first embodiment of the present invention;

FIG. 6 shows instruction structure examples for the processor core and the extension unit in the case of halting a clock CLKC for the processor core, according to the extensive processor of the first embodiment of the present invention;

FIG. 7 shows an illustrative block diagram of an extensive processor according to the second embodiment of the present invention;

FIG. 8 shows instruction structure examples for the processor core and the extension unit in the case of halting a pipeline for the processor core, according to the extensive processor of the second embodiment of the present invention;

FIG. 9 shows an instruction code configuration including a halt cycle count (SCYN) field;

FIG. 10 shows an illustrative block diagram of an extensive processor according to the third embodiment of the present invention; and

FIG. 11 shows an illustrative block diagram of an extensive processor according to the fourth embodiment of the present invention;

### DETAILED DESCRIPTION OF THE EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

Generally, and as is conventional in the representation of the circuit blocks, it will be appreciated that the various drawings are not drawn to scale from one figure to another nor inside a given figure, and in particular that the circuit diagrams are arbitrarily drawn for facilitating the reading of the drawings.

In the following descriptions, numerous specific details are set forth such as specific signal values, etc. to provide a thorough understanding of the present invention. However, it will be obvious to those skilled in the art that the present invention may be practiced without such specific details. In other instances, circuits well-known have been shown in block diagram form in order to not obscure the present invention with unnecessary detail.

Referring to the drawings, embodiments of the present invention are described below. The same or similar reference numerals are attached to identical or similar parts among the following drawings. The embodiments shown below exemplify an apparatus and a method that are used to implement the technical ideas according to the present invention, and do not limit the technical ideas according to the present invention to those that appear below. These technical ideas, according to the present invention, may receive a variety of modifications that fall within the claims.

### COMPARATIVE EXAMPLE

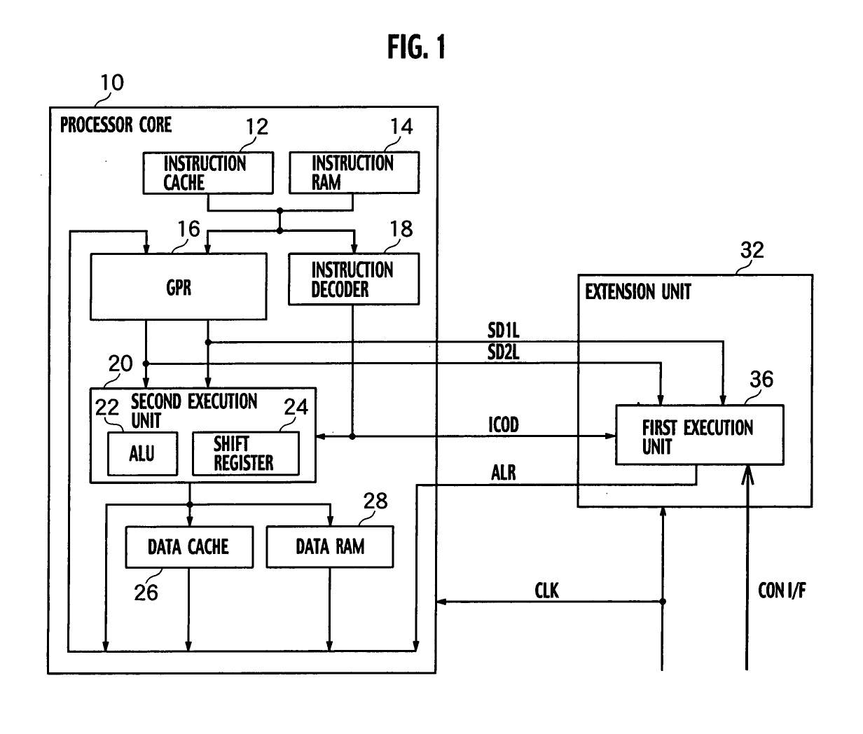

The extensible processor, which is a comparative example according to the present invention, is organized from a processor core 10 and an extension unit 32, as shown in FIG. 1. The processor core 10 and the extension unit 32 are given the same clock speed, because the processor core 10 and the extension unit 32 have the same clock CLK. Moreover, a source data line SD1L, which transmits source data 1; a source data line SD2L, which transmits source data 2; an instruction code transmission line, which transmits an instruction code ICOD; and a calculation result transmission line, which transmits a calculation result ALR are provided between the processor core 10 and the extension unit 32. A configuration interface line CON I/F is connected to the extension unit 32.

The processor 10 is organized from an instruction cache 12, an instruction RAM 14, a general-purpose register 16, an instruction decoder 18, a second execution unit 20, a data cache 26, and a data RAM 28. The extension unit 32 includes a first execution unit 36. An instruction cache 12 and an instruction RAM 14 are connected to the general-purpose register 16 and the instruction decoder 18. The instruction decoder 18 is further connected to the second execution unit 20 and the first execution unit 36. The general purpose-register (GPR) 16 transmits source data 1 and source data 2 to the second execution unit 20, and is connected to the first execution unit 36 via a source data line SD1L, which allows transmission of the source data 1, and a source data line SD2L, which allows transmission of the source data 2. The second execution unit 20 includes an arithmetic and logic unit (ALU) 22 and a shift register 24; bus lines extend from the second execution unit 20 to the data cache 26 and the data RAM 28. Furthermore, the output line that transmits the calculation result ALR from the first execution unit 36 is connected to each of the output line of the second execution unit 20, the output line of the data cache 26 and the data RAM 28. Furthermore, the output line, jointly connected in the above manner, is fed back to the general-purpose register 16.

The above-discussed processor core 10 is an extensible processor core. An extension unit 32 such as a calculation circuit that is suitable for an application is externally attached, that is, to the outside of the processor core 10 so that high performance can be achieved. Usage of a reconfigurable logic circuit made up of, for example, a field programmable gate array (FPGA) for the extension unit 32 allows a single LSI to deal with a plurality of applications; and an efficient calculation unit can be provided, by changing the function of the extension unit 32 within an application.

The “extensible processor” according to an embodiment of the present invention is a processor having an extension unit on the outside of the processor core. As an example, in the case of the extension unit having a structure of a calculation unit such as “reconfigurable” logic circuit, a processor having a reconfigurable calculation unit may also be included in the “extensible processor” according to the embodiment of the present invention. A basic structure of the first embodiment according to the present invention as well as an extensible processor having an operating mode that allows a clock halt for the processor core are explained. An extensible processor according to the second embodiment of the present invention includes an operating mode that allows halting of a pipeline for the processor core is explained. An extensible processor according to the third and the fourth embodiment of the present invention, which includes a reconfigurable logic circuit in an extension unit, is explained.

(First Embodiment)

To begin with, the basic structure of an extensible processor according to an embodiment of the present invention is explained, and the detailed structure of the embodiment is then explained.

(Basic Structure)

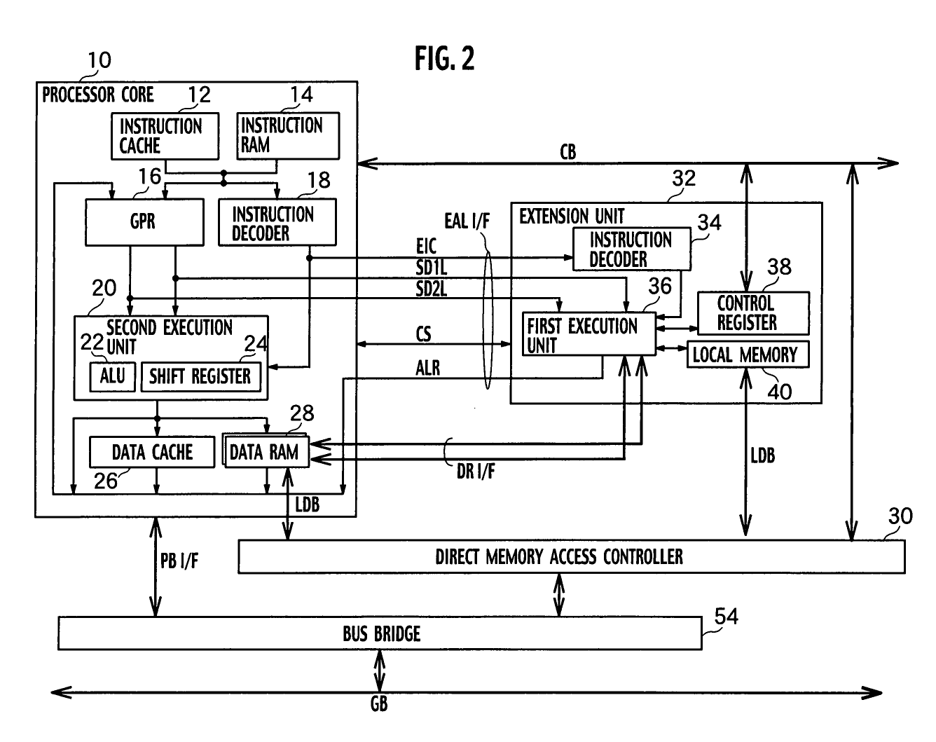

The basic structure of the extensible processor according to the first embodiment of the present invention is made up of a processor core 10, a direct memory access controller (DMAC) 30, an extension unit 32, a bus bridge 54, a global bus GB, and a control bus CB, as shown in FIG. 2. An extended calculation interface line EAL I/F is provided between the processor core 10 and the extension unit 32. The EAL I/F includes a source data line SD1L, which transmits source data 1; a source data line SD2L, which transmits source data 2; a line, which transmits an extended instruction code EIC; a line, which transmits a control signal CS; and a line, which transmits a calculation result ALR connected between the processor core 10 and the extension unit 32. A control bus CB connects the processor core 10 and the extension unit 32. A local data bus LDB connects the DMAC 30 and the extension unit 32. And also, the local data bus LDB connects the DMAC 30 and the data RAM 28. A processor bus interface line PB I/F connects the processor core 10 and the bus bridge 54. Further, a global bus GB is connected to the bus bridge 54.

The processor core 10 is organized from an instruction cache 12, an instruction RAM 14, a general-purpose register 16, an instruction decoder 18, a second execution unit 20, a data cache 26, and a data RAM 28. The extension unit 32 is made up of an instruction decoder 34, a first execution unit 36, a control register 38, and local memory 40. The instruction cache 12 and the instruction RAM 14 are connected to the instruction decoder 18. The instruction decoder 18 is further connected to the second execution unit 20 and the instruction decoder 34. The general-purpose register 16 transmits source data 1 and source data 2 to the second execution unit 20, and is connected to the first execution unit 36 via a source data line SD1L and a source data line SD2L. The second execution unit 20 includes an ALU 22 and a shift register 24; bus lines extend from the second execution unit 20 to the data cache 26 and the data RAM 28. Furthermore, the output line that transmits the calculation result is jointly connected to the output line of the second execution unit 20, and the output lines of the data cache 26 and data RAM 28. Furthermore, the jointly connected output line is fed back to the general-purpose register 16. Moreover, a data RAM interface line DR I/F connects the first execution unit 36 and the data RAM 28. A local data bus LDB connects the DMAC 30 and the data RAM 28.

In the extension unit 32, a signal from the instruction decoder 34 is transmitted to the first execution unit 36. The first execution unit 36, the control register 38, and the local memory 40 communicate with one another by transmitting a signal. The control register 38 is coupled to the processor core 10 via the control bus CB.

The entirety of the block diagram of FIG. 2 configures a system-on-chip (SOC) semiconductor LSI circuit, and configures a processor called a “custom processor” as a single functional block at the same time. The global bus GB is a so-called on-chip bus, and couples each block within the SOC. The function of each unit is described below.

The first execution unit 36 receives data from the processor core 10, performs the calculation, and then returns the calculation result ALR to the processor core 10. The extension unit 32 includes a control register 38. Data stored in the control register 38 is read out via the control bus CB by the processor core 10, or data is written in the same. The extension unit 32 includes local memory 40. The first execution unit 36 utilizes data stored in the local memory 40, performing calculation, or its execution result is written in the local memory 40. The first execution unit 36 may access the data RAM 28 that configures memory embedded in the processor core 10.

The DMAC 30 performs data transmission between the internal memory of the custom processor (e.g., the data RAM 28 in the processor core 10) and between internal units of the custom processor. Since the extension unit 32 really has embedded local memory 40, the local memory 40 can also be a data transmission target of the DMAC 40.

The first execution unit 36 of the extension unit 32 can provide high performance using the internal data RAM 28 of the processor core 10. Since usage of the local memory 40 of the extension unit 32 itself allows an optimal memory configuration, a higher performance is achieved.

It is noted that the internal control register 38 of the extension unit 32, the internal local memory 40 of the extension unit 32, and the internal data RAM 28 of the processor core 10, as shown in the example of FIG. 2, are not always necessary.

The processor core 10 is a central processor of the above-mentioned functional block, and includes an extended calculation interface line EAL I/F for the extension unit 32.

The extension unit 32 performs an operation in conformity with a direction or an instruction from the processor core 10. An extended instruction code EIC, sent from the processor core 10, is interpreted by the instruction decoder 34. The first execution unit 36 performs an operation. The local memory 40 inputs and outputs from/to the first execution unit 36 for its operation. The control register 38 functions as a register, so as to control the operation of the extension unit 32 from the control bus CB.

The DMAC 30 performs data transmission within the above-described functional block, and data transmission between the inside of the functional block and the outside of the functional block. Setting the transmission information, etc. is performed via the control bus CB from the processor core 10.

The bus bridge 54 connects the inside of the aforementioned functional block and the outside thereof (the global bus GB.) The control bus CB contains bus lines that are used to write to the control register 38 in the DMAC 30 or the extension unit 32, and read out from the control register 38.

The extended calculation interface line EAL I/F configures an interface that is used for the processor core 10 to cooperate with the extension unit 32. The extended calculation interface line EAL I/F includes: an extended instruction code EIC for sending an instruction code from the processor core 10 to the extension unit 32; source data 1 and source data 2 that are used to send a value stored in the general-purpose register 16 of the processor core 10; a calculation result ALR that is a calculation result sent from the extension unit 32 to the processor core 10, and a control signal CS, as described above. The control signal CS includes signals such as “valid signal”, which indicates that an instruction to the extension unit 32 is valid, or an “invalidation signal”, which allows invalidation of execution.

The local data bus LDB is deployed between the DMAC 30 and the local memory 40 and between the DMAC 30 and the data RAM 28, and functions as an internal data bus of the aforementioned functional block, as described above.

The data RAM interface line DR I/F is an interface that is used for the first execution unit 36 in the extension unit 32 to access the internal data RAM 28 of the processor core 10, and specifically provides a data read/write function.

The processor bus interface line PB I/F functions as an interface that is used for the processor core 10 to access the global bus GB.

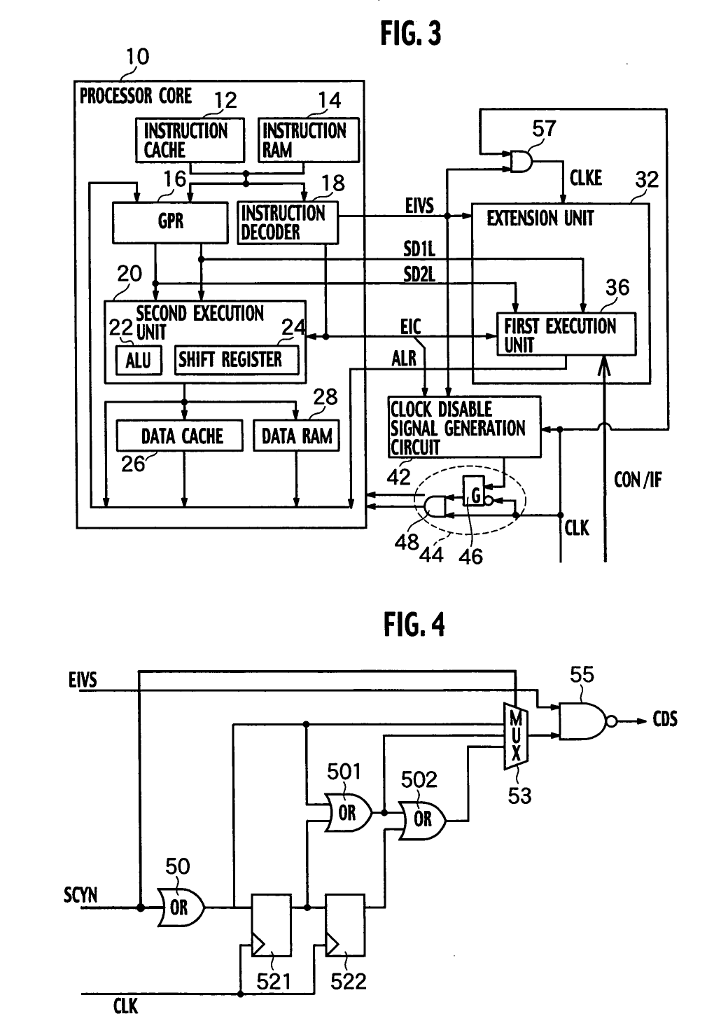

The extensible processor according to the first embodiment of the present invention, as shown in FIG. 3, includes the basic structure shown in FIG. 2 where a clock disable signal generation circuit 42 and a clock gating circuit 44 are additionally deployed between the processor core 10 and the extension unit 32 so that a clock CLK for the processor core 10 can be halted. An extended instruction code EIC branched out from the instruction decoder 18 is provided to the clock disable signal generation circuit 42. The clock gating circuit 44 is made up of an AND gate 48 and a latch 46. The clock CLK is provided to both the clock disable signal generation circuit 42 and the clock gating circuit 44. The output from the clock disable signal generation circuit 42 is transmitted to the latch 46 in the clock gating circuit 44; and the output of the AND gate 48 is provided to the processor core 10.

With reference to FIG. 3, an extended instruction code EIC for the extension unit 32 is sent from the instruction decoder 18. Alternatively, a structure from which the extended instruction code EIC is branched out just before the instruction decoder 18 is possible. In this case, an extended instruction valid signal EIVS is provided to the extension unit 32 from the instruction decoder 18, as shown in FIG. 3. It is noted that in the case where an extended instruction code EIC received from the instruction decoder 18 is used, the structure with the extended instruction valid signal EIVS being given to the extension unit 32 is normal.

A clock CLKE for the extension unit 32 is generated as the output signal from the AND gate 57 that inputs the clock CLK and the extended instruction valid signal EIVS, as shown in FIG. 3. It is noted that since the internal structure of the processor core 10 and internal structure of the extension unit 32 shown in FIG. 3 are the same as the basic structure shown in FIG. 2, its detailed explanation is omitted. Regarding the internal structure of the extension unit 32 shown in FIG. 3, the first execution unit 36 is illustrated; however, illustration of the control register 38 and the local memory 40 included in the extension unit 32 shown in FIG. 2 is omitted. The control register 38 and the local memory 40 may be located on the outside of the extension unit 32.

It is noted that since the bus lines or the like, which are used to connect between the processor core 10 and the extension unit 32 are the same as the basic structure shown in FIG. 2, a detailed explanation is omitted.

The extensible processor according to the first embodiment of the present invention includes the processor core 10 and the extension unit 32 being synchronized by halting or temporarily stopping the processor core 10 in conformity with an extended instruction code EIC for the extension unit 32. In the case where the extension unit 32 is organized with a structure including, for example, a reconfigurable logic circuit, since the reconfigurable logic circuit operates at a low speed, the extension unit 32 uses a plurality of clock cycles so as to perform an operation. At this time, the pipeline of the processor core 10 needs to halt (or be temporarily stopped) until the operation of the extension unit 32 is completed.

With the extensible processor according to the first embodiment of the present invention, a field that indicates the halt cycle count is prepared within an extended instruction code EIC for the extension unit 32, and the processor core 10 is halted based on its field value that indicates the halt cycle count. In order to halt the processor core 10, the clock CLKC supplied to the processor core 10 is halted.

The clock disable signal generation circuit 42, which generates a clock disable signal CDS that causes the clock CLKC for the processor core 10 to stop, is organized by an OR gate 50 that inputs a halt cycle count SCYN; OR gates 501 and 502, which are organized in two stages with the output of the OR gate 50 being input to one thereof; flip-flop circuits 521 and 522, which are cascade-connected so that the output of the OR gate 50 is connected to the first stage; a multiplexer (MUX) 53, which inputs the output of the OR gate 50 and the outputs of the OR gates 501 and 502 and is organized with two stages; and an AND gate 55, which has the output of the multiplexer 53 and the extended instruction valid signal EIVS as input signals and outputs a clock disable signal CDS, as shown in FIG. 4. It is apparent from FIG. 3 that the clock CLK is an input signal for the flip-flop circuits 521 and 522, which are two-stage cascade connected. The outputs of the two-stage cascade connected flip-flop circuits 521 and 522 are coupled to the other input terminals of the OR gates 501 and 502, respectively. The halt cycle count SCYN is provided as a gate signal to the MUX 53.

If the field that indicates the halt cycle count SCYN is organized from two bits, and the value of these bits indicate the halt cycle count SCYN, then, for example, “00” denotes “NO HALT”, “01” denotes “ONE-CYCLE HALT”, “10” denotes “TWO-CYCLE HALT”, and “11” denotes “THREE-CYCLE HALT”. It is possible to halt the clock for a desired time period by providing a signal generated by this circuit (i.e., the clock disable signal) to the clock gating circuit. This is an advantage, since halting the clock allows for a reduction of power consumption.

The extensible processor according to the first embodiment of the present invention provides the halt cycle SCYN from only the extended instruction code EIC; alternatively, it may use another input signal. This is an example method of determining the halt cycle count SCYN by defining a basic halt cycle count when the extension unit 32 is reconfigured and then providing the value from the extension unit 32 to the clock disable signal generation circuit 42. If the basic halt cycle count is two, when the halt cycle count SCYN field in an extended instruction code EIC is “00”, a halt for two cycles will occur.

The extensible processor according to the first embodiment of the present invention has the clock disable signal generation circuit 42 located externally of the processor core 10 and also external to the extension unit 32; alternatively, the clock disable signal generation circuit 42 may be located in the processor core 10, or in the extension unit 32.

It is assumed that the clock disable signal generation circuit 42 in the extensible processor according to the first embodiment of the present invention is a circuit that is used when the clock CLKC and the clock CLKE have the same phase and the same frequency. Alternatively, even when the clock CLKE for the extension unit 32 results from frequency-dividing the clock CLKC for the processor core 10, the clock disable signal generation circuit 42 may be organized as a circuit resulting from consideration of the clock CLK phase.

(Operational Mode)

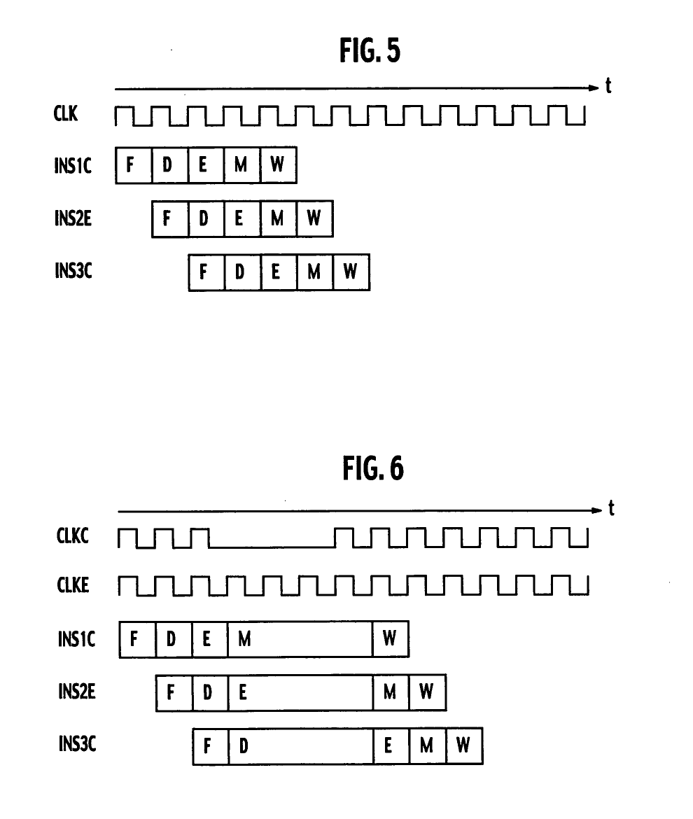

With the extensible processor according to the first embodiment of the present invention, when the instructions for the extension unit 32 is also executed with the same clock count as that for the processor core 10, the instructions for the processor core 10 and the extension unit 32 are organized as shown in FIG. 5. The pipeline for the processor core 10 is originally organized from, for example, five stages such as an instruction fetch (F), an instruction decode (D), an execution (E), a memory access (M), and a write-back (W) stage, wherein each stage takes one clock cycle and each stage operates in an overlapping manner. In the case of the instructions for the extension unit 32 being executed with the same clock count as that for the processor core 10, instructions 1, 2, and 3 for the processor core 10 are represented by INS1C, INS2E, and INS3C, respectively, relative to the clock CLK, as shown in FIG. 5.

With the extensible processor according to the first embodiment of the present invention, the instructions for the processor core 10 and the extension unit 32 when the clock CLKC for the processor core 10 is halted are organized as shown in FIG. 6. If an operation by the extension unit 32 takes four clock cycles, the processor core 10 is halted for three clock cycles. Therefore, an instruction 1 for the processor core 10, an instruction 2 for the extension unit 32, and an instruction 3 for the processor core 10 are represented by INS1C, INS2E, and INS3C, respectively, relative to the clock CLKC for the processor core 10 and clock CLKE for the extension unit 32, as shown in FIG. 6. Namely, the proceeding operation of the M stage for the instruction 1 (INS1C), halts until the E stage for the subsequent instruction 2(INS2E) for the extension unit 32 is completed. In the same manner, the following operation of the D stage for the instruction 3 (INS3C), halts until the E stage for the proceeding instruction 2(INS2E) for the extension unit 32 is completed.

With the extensible processor according to the first embodiment of the present invention, the processor core 10 and the extension unit 32 can be synchronized, thereby facilitating use of a lower speed logic circuit.

(Second Embodiment)

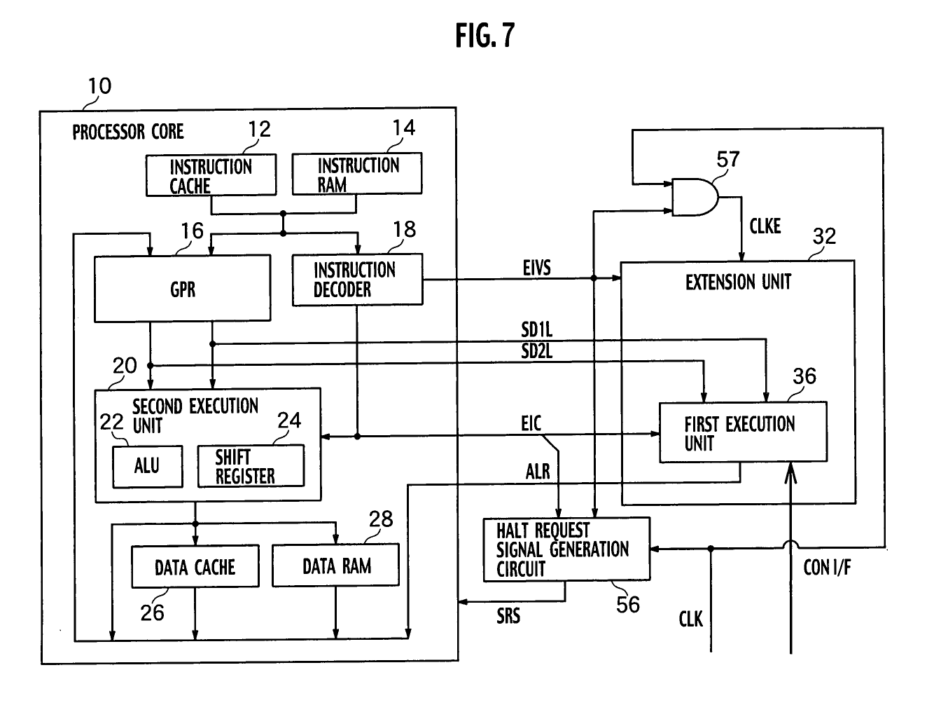

The extensible processor according to the second embodiment of the present invention, as shown in FIG. 7, includes by a halt request signal generation circuit 56 additionally provided between the processor core 10 and the extension unit 32 in the basic structure shown in FIG. 2. An extended instruction code EIC branched out from the instruction decoder 18 is provided to the halt request signal generation circuit 56. The output of the halt request signal generation circuit 56 is provided to the processor core 10. It is noted that since the internal structure of the processor core 10 and internal structure of the extension unit 32 are practically the same as the basic structure shown in FIG. 2, a detailed explanation thereof is omitted. Regarding the internal structure of the extension unit 32 shown in FIG. 7, the first execution unit 36 is illustrated; however, the control register 38 and the local memory 40 included in the extension unit 32 that is shown in FIG. 2 are not illustrated. That is to say, the illustration thereof is omitted. The control register 38 and the local memory 40 may be located externally of the extension unit 32.

It is noted that since the bus lines or the like, which are used to connect the processor core 10 and the extension unit 32, are the same as the basic structure shown in FIG. 2, a detailed explanation thereof is omitted.

The extensible processor according to the second embodiment of the present invention, as shown in FIG. 7, includes the halt request signal generation circuit 56 additionally located between the processor core 10 and the extension unit 32 with the basic structure shown in FIG. 2 so as to halt the pipeline for the processor core 10, rather than the clock CLKC for the processor core 10.

With reference to FIG. 7, an extended instruction code EIC for the extension unit 32 is output from the instruction decoder 18. Alternatively, a structure from which the extended instruction code is branched out just before the instruction decoder 18 is possible, as in the case of first embodiment shown in FIG. 3. In this case, an extended instruction valid signal EIVS is output to the extension unit 32 from the instruction decoder 18 as shown in FIG. 7. It is noted that when an extended instruction code EIC is output from the instruction decoder 18, the structure with the extended instruction valid signal EIVS being input to the extension unit 32 is normal.

The clock CLKE for the extension unit 32 is provided as the output signal from the AND gate 57 that inputs the clock CLK and the extended instruction valid signal EIVS as shown in FIG. 7; this is also the same as the first embodiment shown in FIG. 3.

(Operational Mode)

The pipeline for the processor core 10 is originally organized from, for example, five stages such as an instruction fetch (F), an instruction decode (D), an execution (E), a memory access (M), and a write-back (W) stage, wherein each stage takes one clock, and each stage operates in an overlapping manner. In the case of the instructions for the extension unit 32 being executed with the same clock count as that for the processor core 10, an instruction 1 (INSC1) for the processor core 1, an instruction 2(INS2E) for the extension unit 32, and an instruction 3 (INS3C) for the processor core 10 are represented by INS1C, INS2E, and INS3C, respectively, which are relative to the clock CLK, as shown in FIG. 5.

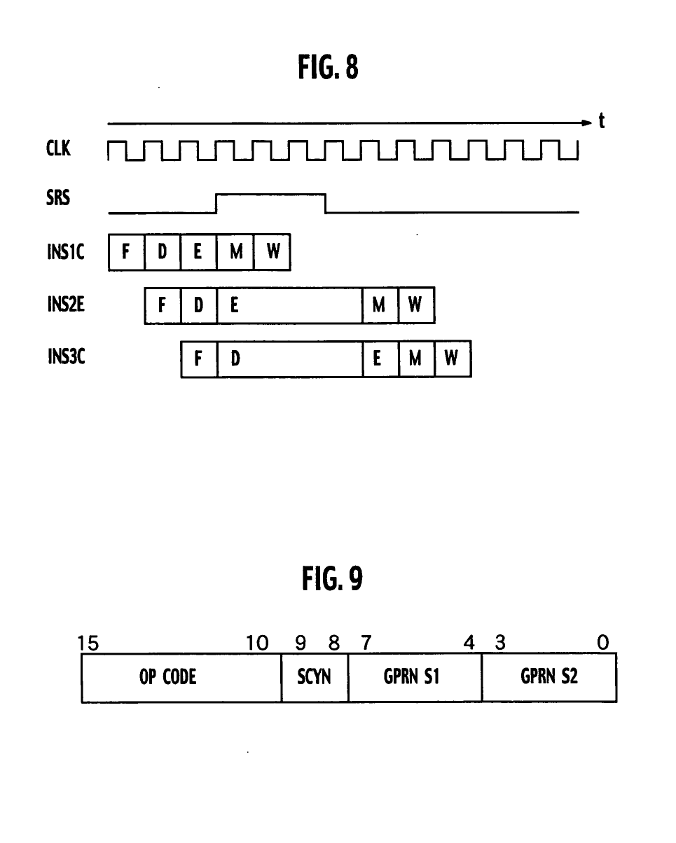

With the extensible processor according to the second embodiment of the present invention, the instructions for the processor core 10 and the extension unit 32 when the pipeline for the processor core 10 is halted are organized as shown in FIG. 8. Therefore, once the halt request signal SRS issued from the halt request signal generation circuit 56, which has received the clock CLK, has reached the processor core 10, the instruction 1 for the processor core 10, the instruction 2 for the extension unit 32, and the instruction 3 for the processor core 10 are represented by INS1C, INS2E, and INS3C, respectively. When the halt request signal SRS relative to the clock CLK exists, as shown in FIG. 8, since it is easy to halt only a target stage other than the clock CLK, halting the proceeding instruction 1(INS1C) for the processor core 10 is unnecessary. Thus completing the processes until the W stage for the proceeding instruction 1 (INS1C) for the processor core 10 is possible. To the contrary, the subsequent instruction 3(INS3C) for the processor core 10 is halted at the D stage in the same way as the operation mode in which the processor core clock CLKC shown in FIG. 6 is halted, and after the E stage for the instruction 2(INS2E) for the extension unit 32 is completed, the E stage for the subsequent instruction 3(INS3C) is executed.

(Halt Request Generation Circuit)

The halt request signal generation circuit 56 in an extensible processor according to the second embodiment of the present invention may be organized with substantially the same circuit as the clock disable signal generation circuit 42 shown in FIG. 4. While it is assumed that the halt request signal generation circuit 56 in the extensible processor according to the second embodiment of the present invention is a circuit for the case where the clock CLK for the processor core 10 and clock CLK for the extension unit 32 have the same phase and the same frequency, even in the case where the clock CLKE for the extension unit 32 results from frequency-dividing the clock CLKC for the processor core 10, it is possible to configure an alternative circuit based on the clock CLK phase.

(Modified Example of the Second Embodiment)

The extensible processor according to the second embodiment of the present invention includes reconfigurable logic circuit that configures the halt request signal generation circuit 56 shown in FIG. 7. With the halt request signal generation circuit 56 organized with the reconfigurable logic circuit, decoding the OP code field of an instruction code easily permits inclusion of a halt cycle count SCYN. Specifically, it is unnecessary for the instruction code to include a specific halt cycle count field. Thus effective utilization of the bit pattern is possible.

Note that the instruction code having the halt cycle count (SCYN) field is organized as shown in FIG. 9. When the instruction length for the extension unit 32 is 16 bits, and four bits (for sixteen registers) times two, and two bits thereof are used for the general purpose register number GPRN and the halt cycle count SCYN, respectively, only six bits can be used for the OP codes. Thus, the maximum number of different instructions is sixty-four. In FIG. 9, GPRN S1 and GPRN S2 denote the general-purpose register number for a source 1 and general purpose register number for a source 2, respectively. In reality, since there are instructions or the like that use an immediate value, the number of different instructions further decreases. At this time, if two bits for the halt cycle count SCYN are unnecessary, eight bits become available for the OP codes, which allow for the definition of the maximum number of 256 instructions.

Further, while with an extensible processor according to the first embodiment of the present invention, a method of halting the processor core 10 by halting the clock CLKC for the processor core 10 is described. Halting the pipeline for the processor core 10 is also possible as with the extensible processor according to the second embodiment of the present invention, by utilizing the same clock disable signal CDS as a signal that requests a pipeline stall.

(Third Embodiment)

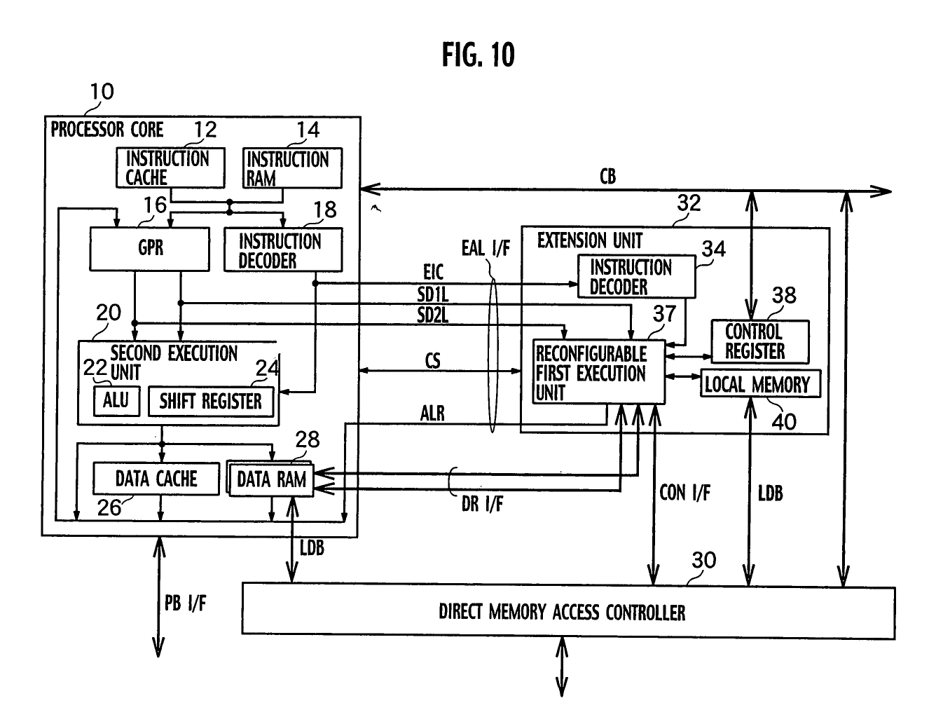

The basic structure of an extensible processor according to the third embodiment of the present invention is made up of a processor core 10, a DMAC 30, and an extension unit 32, as shown in FIG. 10. An expanded calculation interface line EAL I/F is provided between the processor core 10 and the extension unit 32. Moreover, a source data line SD1L, which transmits source data 1; a source data line SD2L, which transmits source data 2; a line, which transmits an extended instruction code EIC; a line, which transmits a control signal CS; and a line, which transmits a calculation result ALR are provided between the processor core 10 and the extension unit 32. Moreover, a control bus CB is connected between the processor core 10 and the extension unit 32. A local data bus LDB is connected between the DMAC 30 and the extension unit 32. The processor bus interface line PB I/F is connected to the processor core 10.

The processor 10 is organized from an instruction cache 12, an instruction RAM 14, a general-purpose register 16, an instruction decoder 18, a second execution unit 20, a data cache 26, and a data RAM 28. The extension unit 32 is made up of an instruction decoder 34, a reconfigurable first execution unit 37, a control register 38, and local memory 40. The instruction cache 12 and the instruction RAM 14 are connected to the general-purpose register 16 and the instruction decoder 18. The instruction decoder 18 is further connected to the second execution unit 20 and the instruction decoder 34. The general-purpose register 16 transmits source data 1 and source data 2 to the second execution unit 20, and is connected to the reconfigurable first execution unit 37 via a source data line SD1L, which allows transmission of the source data 1, and a source data line SD2L to transmit the source data 2. The second execution unit 20 includes an ALU 22 and a shift register 24; bus lines extend from the second execution unit 20 to the data cache 26 and the data RAM 28. Furthermore, the line that transmits the calculation result from the reconfigurable first execution unit 37 is jointly connected to the output line of the second execution unit 20, and the output lines of the data cache 26 and the data RAM 28. The jointly connected output line is fed back to the general-purpose register 16. A data RAM interface line DR I/F connects the reconfigurable first execution unit 37 and the data RAM 28. A local data bus LDB is connected between the DMAC 30 and the data RAM 28. A reconfiguration interface line CON I/F connects the reconfigurable first execution unit 37 and the DMAC 30. In the extension unit 32, a signal from the instruction decoder 34 is transmitted to the reconfigurable first execution unit 37, and a signal is transmitted among the first execution unit 37, the control register 38, and the local memory 40. The control register 38 is coupled to the processor core 10 via the control bus CB. The aforementioned extended calculation interface line EAL I/F includes an extended instruction code EIC, a source data 1 line SD1L, a source data 2 line SD2L, a control signal CS, and a calculation result ALR.

The structure in its entirety is shown in the block diagram of FIG. 10 configuring a system-on-chip (SOC) semiconductor LSI circuit, and configuring a processor called a “custom processor” as a single functional block at the same time. The global bus GB (which is omitted in FIG. 10) is a so-called on-chip bus, and couples each block within the SOC. The function of each unit is described below.

The processor core 10 is a central processor of the above-mentioned functional block, and includes an extended calculation interface line EAL I/F for the extension unit 32.

The extension unit 32 performs an operation in conformity with a direction or an instruction from the processor core 10. An extended instruction code EIC, sent from the processor core 10, is interpreted by the instruction decoder 34. The reconfigurable first execution unit 37 performs an arithmetic operation. The local memory 40 performs as an input and/or output unit from/to the reconfigurable first execution unit 37 for its arithmetic operation. The control register 38 functions as a register, so as to control the operation of the extension unit 32 from the control bus CB.

The extended calculation interface line EAL I/F configures an interface that is used for the processor core 10 to cooperate with the extension unit 32. The extended calculation interface line EAL I/F includes: an extended instruction code EIC for sending an instruction code from the processor core 10 to the extension unit 32; source data 1 and source data 2 that are used to send a value stored in the general-purpose register 16 of the processor core 10; a calculation result ALR that is a calculation result sent from the extension unit 32 to the processor core 10, and a control signal CS, as described above. The control signal CS includes signals such as “valid signal”, which indicates that the instruction for the extension unit 32 is valid, or an “invalidation signal”, which signals that the instruction is not valid, and will not allow execution.

The local data bus LDB is located between the DMAC 30 and the local memory 40 and between the DMAC 30 and the data RAM 28, and functions as an internal data bus of the aforementioned functional block, as described above. The data RAM interface line DR I/F is an interface that is used for the reconfigurable first execution unit 37 in the extension unit 32 to access the internal data RAM 28 of the processor core 10, and specifically provides a data read/write function.

The processor bus interface line PB I/F functions as an interface that is used for the processor core 10 to access the global bus GB (not shown in the drawing).

The reconfigurable first execution unit 37 is specifically organized from a reconfigurable logic circuit. The reconfigurable logic circuit refers to a circuit such as a field programmable gate array (FPGA).

The DMAC 30 is used for data transmission, which is needed to process data in the above-described functional block, data transmission between the internal functional block and the outside of the functional block, and data transmission, which is used for the configuration of the reconfigurable first execution unit 37. Setting the transmission information, etc. is performed via the control bus CB from the processor core 10.

The control bus CB contains bus lines that are used to write to the internal control register 38 of the DMAC 20 or the extension unit 32, and read out from the control register 38. A signal that directs changeover between the data processing mode for the reconfigurable first execution unit 37 and the configuration mode is transmitted via the control bus CB.

An extensible processor according to the third embodiment of the present invention corresponds to, for example, a custom processor that uses a reconfigurable logic circuit such as FPGA, as the first execution unit 37. The reconfigurable first execution unit 37 specifically configures a reconfigurable calculation unit. The use of a reconfigurable logic circuit as a calculation unit for the extension unit 32 allows change in the function of the extension unit 32 in accordance with an application. Such a structure allows the same custom processor to deal with different applications/functions. Namely, it is possible to change to a different function from an original function. Moreover, a dynamical reconfiguration of the reconfigurable first execution unit 37 can be applied for different operational functions, which can be switched for each divided time within an application and then be executed for each divided time. In this case, while a plurality of calculation units are needed conventionally, since the same extension unit 32 executes different functions, a calculation unit alone can deal with all of the different functions.

In general, since the reconfigurable logic circuit has a configuration interface line CON I/F for changing a configuration, the logical state can be changed, by providing configuration information from the CON I/F line. The configuration information may be provided through data transmission, under the control by the DMAC 30. Reconfiguration may be performed, by transmitting configuration information to the extension unit 32 from, for example, memory located externally of a custom processor.

In the case of the extension unit 32 including, for example, data RAM 28, the DMAC 30 also performs data transmission to the data RAM 28. At such time, the interface between the DMAC 30 and the extension unit 32 may be organized with two sub-interfaces: one for normal data transmission and the other for reconfiguration. Alternatively, it may be organized with a single interface with a branch that exists within the extension unit 32.

Since the operational speed of the reconfigurable logic circuit is generally and disadvantageously low, parallel operation may be conducted in order to provide high performance. In this case, a problem with the data-supplying capability may occur. However, since with the structure of an extensible processor according to the third embodiment of the present invention, the adjacent local memory 40 is available and data can be efficiently provided. Since use of internal memory of the extension unit 32 allows an optimal configuration, higher performance may be achieved.

(Modified Example 1 of the Third Embodiment)

In the extensible processor according to the third embodiment of the present invention, a structure example where the instruction decoder 34 in the extension unit 32 is located externally of the reconfigurable first execution unit 37 is shown in FIG. 10. However, the present invention is not limited to this structure. Alternatively, the instruction decoder 34 itself may be organized with the same logic circuit as the reconfigurable first execution unit 37. In this case, the instruction decoder 34 is organized within the reconfigurable first execution unit 37.

(Modified Example 2 Of the Third Embodiment)

In an extensive processor according to the third embodiment of the present invention, a signal that directs changeover between the data processing mode for the reconfigurable first execution unit 37 and the configuration mode is transmitted via the control bus CB. However, it is not always necessary for the mode changeover to be performed via the control bus CB. Alternatively, the CON I/F for configuration data transmission, as shown in FIG. 10, may be used.

(Fourth Embodiment)

Reconfigurable logic circuits need to receive configuration data. The extensible processor according to the fourth embodiment of the present invention includes the local memory 40 in the extension unit 32 being stored with the configuration data. Data to be provided to the local memory 40 is transmitted from the DMAC 30 via the local data bus LDB. The DMAC 30 transmits the data stored in the external memory to the local memory 40. The data from the external memory is transmitted to the DMAC 30 via a bus bridge (omitted in the drawing) and a global bus GB (omitted in the drawing). Alternatively, the internal data RAM 28 of the processor core 10 may be used as external memory. In this case, data is transmitted to the DMAC 30 via the local data bus LDB, which is connected to the data RAM 28, and that data is then written in the local memory 40 via the DMAC 30.

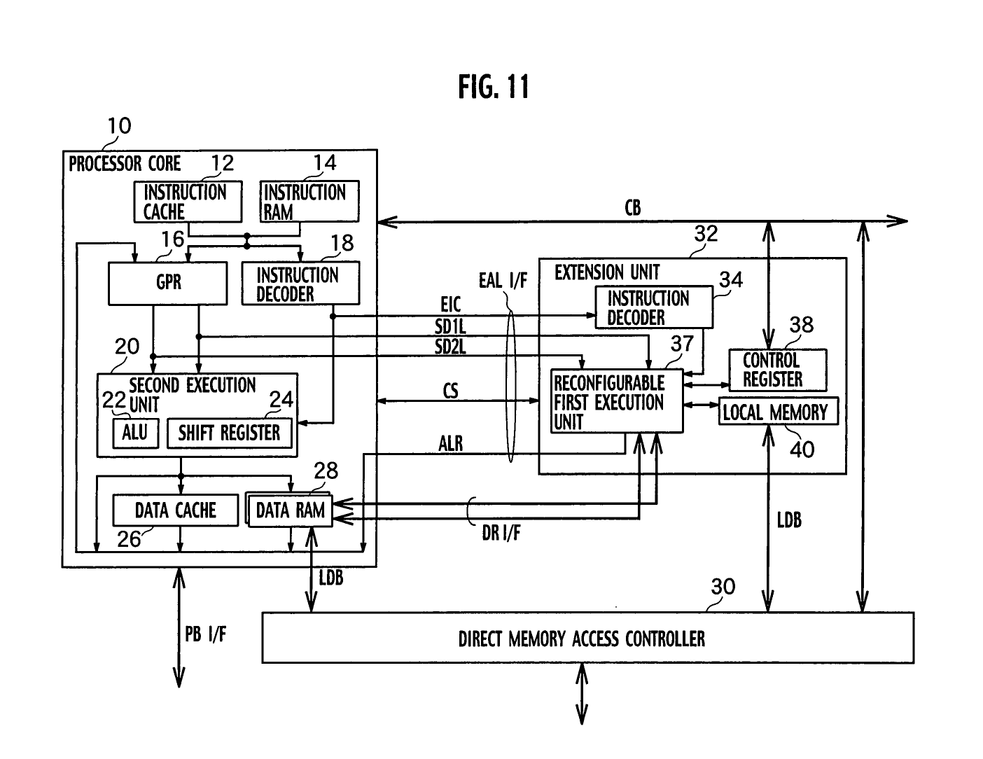

The basic structure of an extensible processor according to the fourth embodiment of the present invention is made up of a processor core 10, a DMAC 30, and an extension unit 32, as shown in FIG. 11. Since the internal structure of the processor core 10 and extension unit 32 is substantially the same as that of FIG. 10, an explanation thereof is omitted. Moreover, since the bus lines or the like between the processor core 10 and extension unit 32 are substantially the same as that of FIG. 10, an explanation thereof is omitted.

The reconfigurable first execution unit 37 performs an arithmetic operation. The local memory 40 performs as an input and/or output unit from/to the reconfigurable first execution unit 37 for its arithmetic operation. The extensible processor according to the fourth embodiment of the present invention provides for the local memory 40 in the extension unit 32 to be stored with this configuration data as is described above.

The local data bus LDB is located between the DMAC 30 and the local memory 40 and between the DMAC 30 and the data RAM 28, and functions as an internal data bus of the aforementioned functional block.

The data RAM interface line DR I/F is an interface that is used for the reconfigurable first execution unit 37 in the extension unit 32 to access the internal data RAM 28 of the processor core 10, and specifically provides a data read/write function.

The processor bus interface line PB I/F functions as an interface used for the processor core 10 to access the global bus GB (not shown in the drawing). The reconfigurable first execution unit 37 is specifically organized from a reconfigurable logic circuit. The reconfigurable logic circuit refers to a circuit such as a field programmable gate array (FPGA).

The DMAC 30 is used for data transmission, which is needed to process data in the above-mentioned functional block, data transmission between the internal functional block and outside of the functional block, and data transmission, which is used for the configuration of the reconfigurable first execution unit 37. Setting the transmission information, etc. is performed via the control bus CB from the processor core 10.

The control bus CB contains bus lines that are used to write to the control register 38 in the DMAC 20 or the extension unit 32, and read out from a status register. A signal that directs changeover between the data processing mode for the reconfigurable first execution unit 37 and the configuration mode is transmitted via the control bus CB.

An extensible processor according to the fourth embodiment of the present invention corresponds to, for example, a custom processor that uses a reconfigurable logic circuit organized with, for example, FPGA, as the reconfigurable first execution unit 37 in the extension unit 32. The reconfigurable first execution unit 37 specifically configures a reconfigurable calculation unit. The use of a reconfigurable logic circuit as a calculation unit for the extension unit 32 allows change in the function of the extension unit 32 in accordance with an application. This allows the same custom processor to deal with different applications/functions. Specifically, it is possible to change to a different function from the original function. Moreover, a dynamical reconfiguration of the reconfigurable first execution unit 37 can be applied for different operational functions, which can be switched for each divided time within an application and then be executed for each divided time. In this case, while a plurality of calculation units are needed conventionally, since the same extension unit 32 executes different functions, a calculation unit alone can deal with all of the different functions.

In the case of the extension unit 32 including memory such as data RAM, the DMAC 30 also performs data transmission to the memory. The interface between the DMAC 30 and the extension unit 32 may be organized with a single interface with a branch that exists within the extension unit. It may be organized with two sub-interfaces: one for normal data transmission and the other for reconfiguration; alternatively.

Since the operational speed of the reconfigurable logic circuit is generally and disadvantageously low, parallel operation may be conducted in order to provide high performance. In this case, a problem with the data-supplying capability may occur. However, since with the structure of an extensible processor according to the fourth embodiment of the present invention, the adjacent local memory 40 is available and data can be efficiently provided. Since use of internal memory of the extension unit 32 allows an optimal configuration, higher performance may be achieved.

(Modified Example 1 Of the Foerth Embodiment)

In the extensible processor according to the fourth embodiment of the present invention, a structure example where the instruction decoder 34 in the extension unit 32 is located externally of the reconfigurable first execution unit 37 is shown in FIG. 11. However, the present invention is not limited to this structure. Alternatively, the instruction decoder 34 itself may be organized with the same logic circuit as the reconfigurable first execution unit 37. In this case, the instruction decoder 34 is organized within the reconfigurable first execution unit 37.

(Modified Example 2 of the Fourth Embodiment)

In an extensive processor according to the fourth embodiment of the present invention, a signal that directs changeover between the data processing mode for the reconfigurable first execution unit 37 and the configuration mode is transmitted via the control bus CB. However, it is not always necessary for the mode changeover to be performed via the control bus CB.

With reference to FIG. 11, since it is possible for the DMAC 30 to transmit, for example, the configuration data to the local memory 40 of the extension unit 32, and at the same time for the reconfigurable first execution unit 37 to access the data RAM 28 in the processor core 10 and execute data processing, overheads for configuration data transmission may be hidden.

According to a extensive processor and a semiconductor LSI circuit of the present invention, since the processor core and the extension unit can be synchronized by halting the clock for the processor core and/or the pipeline in conformity with an instruction code for the extension unit, a high efficiency and high performance extensible processor and system-on-chip semiconductor LSI circuit can be provided.

It is natural that the present invention covers a variety of embodiments not described herein. Accordingly, the technical scope of the present invention is defined by only the following claims that appear appropriate from the above explanation.

(Other Embodiments)

While the present invention is described in accordance with the aforementioned embodiments, it should not be understood that the description and drawings that configure part of this disclosure are to limit the present invention. This disclosure makes clear a variety of alternative embodiments, working examples, and operational techniques for those skilled in the art. Accordingly, the technical scope of the present invention is defined by only the claims that appear appropriate from the above explanation.

Various modifications will become possible for those skilled in the art after receiving the teachings of the present disclosure without departing from the scope thereof.

What is claimed is:

1. A processor comprising:
a processor core including a general-purpose register, an instruction decoder, and a second execution unit;
an extension unit including a first execution unit connected to the processor core; and
a direct memory access controller connected to both the processor core and the extension unit.

2. The processor of claim 1, further comprising a control bus connected to the processor core and the extension unit.

3. The processor of claim 2, further comprising a clock disable signal generation circuit organized to receive an extended instruction code from the instruction decoder and outputs a clock disable signal.

4. The processor of claim 3, further comprising a clock gating circuit organized to receive the clock disable signal and transmits a signal for halting a clock signal for the processor core.

5. The processor of claim 4, wherein the clock disable signal halts the clock signal for the processor core.

6. The processor of claim 2, further comprising a halt request signal generation circuit organized to receive an extended instruction code from the instruction decoder and transmit a halt request signal to the processor core.

7. The processor of claim 2, wherein the first execution unit is a reconfigurable first execution unit.

8. The processor of claim 7, wherein the extension unit further comprises an instruction decoder, a control register, and local memory.

9. The processor of claim 7, wherein the instruction decoder in the extension unit further comprises a reconfigurable logic circuit that is the same as the reconfigurable first execution unit.

10. The processor of claim 7, wherein configuration data provided to the reconfigurable logic circuit, is provided through data transmission from the direct access memory controller via a configuration interface connecting the reconfigurable first execution unit in the extension unit and the direct memory access controller.

11. The processor of claim 8, wherein configuration data provided to the reconfigurable logic circuit is stored in the internal local memory of the extension unit.

12. A semiconductor integrated circuit, comprising:
a semiconductor chip;
a processor core integrated on the semiconductor chip including a general purpose register, an instruction decoder, and a second execution unit;
an extension unit integrated on the semiconductor chip including a first execution unit connected to the processor core;
a direct memory access controller integrated on the semiconductor chip and connected to both the processor core and the extension unit.

13. The semiconductor integrated circuit of claim 12, further comprising a control bus integrated on the semiconductor chip and connected to both the processor core and the extension unit.

14. The semiconductor integrated circuit of claim 13, further comprising a clock disable signal generation circuit integrated on the semiconductor chip and is organized to receive an extended instruction code from the instruction decoder and outputs a clock disable signal.

15. The semiconductor integrated circuit of claim 14, further comprising a clock gating circuit integrated on the semiconductor chip and is organized to receive the clock disable signal and transmits a signal for halting a clock for the processor core to the processor core.

16. The semiconductor integrated circuit of claim 13, further comprising a halt request signal generation circuit integrated on the semiconductor chip and is organized to receive an extended instruction code from the instruction decoder and transmit a halt request signal to the processor core.

17. The semiconductor integrated circuit of claim 13 wherein the first execution unit is a reconfigurable first execution unit.

18. The semiconductor integrated circuit of claim 17, wherein the instruction decoder in the extension unit further comprises a reconfigurable logic circuit that is the same as the reconfigurable first execution unit.

19. The semiconductor integrated circuit of claim 17, wherein configuration data provided to the reconfigurable logic circuit, is provided through data transmission from the direct access memory controller via a configuration interface connecting between the reconfigurable first execution unit in the extension unit and the direct memory access controller.

20. The semiconductor integrated circuit of claim 17, wherein configuration data provided to the reconfigurable logic circuit is stored in the internal local memory of the extension unit.
